(19) United States
(12) Patent Application Publication
(10) Pub. No.: US 2026/0090161 A1
(43) Pub. Date: Mar. 26, 2026

(54) LOW-MODULUS SUPRAMOLECULAR COATING AND FLUID SELF-ASSEMBLY METHOD

(71) Applicant: BEIJING UNIVERSITY OF CHEMICAL TECHNOLOGY, Beijing (CN)

(72) Inventors: Feng SHI, Beijing (CN); Mengjiao CHENG, Beijing (CN); Guiqiang ZHU, Beijing (CN)

(21) Appl. No.: 19/396,657

(22) Filed: Nov. 21, 2025

Related U.S. Application Data
(63) Continuation of application No. PCT/CN2024/095021, filed on May 23, 2024.

(30) Foreign Application Priority Data
May 25, 2023 (CN) 202310603626.0

(51) Int. Cl. H10H 29/03; C09D 7/61

(52) U.S. Cl. CPC H10H 29/03; C09D 7/61

(57) ABSTRACT

The present application provides a low-modulus supramolecular coating and a fluid self-assembly method, which are applied to micro devices and assembly substrate. The modulus of the low-modulus supramolecular coating is 10 MPa or less, and the surface thereof has fluidity; and the low-modulus supramolecular coating is applied to the surfaces of micro devices and the surface of an assembly substrate, and the low-modulus supramolecular coating applied to the surfaces of the micro devices and the low-modulus supramolecular coating applied to assembly positions on the assembly substrate contain complementary supramolecular functional groups. The present application solves the problems in existing fluid self-assemble whereby the transfer efficiency is low, the structure of an assembly substrate is complex, subsequent repairing is difficult, and it is difficult to realize simultaneous classification and assembly of various micro devices.

### CROSS-REFERENCE TO RELATED APPLICATION

This application claims priority to Chinese Patent Application No. 2023106036260, filed on May 25, 2023, entitled “Low-Modulus Supramolecular Coating and Fluid Self-Assembly Method”, filed with the China National Intellectual Property Administration (CNIPA), the entire contents of which are incorporated herein by reference.

### TECHNICAL FIELD

The present application relates to the field of micro-nano manufacturing technology field, and in particular to a low-modulus supramolecular coating applied to micro devices and an assembly substrate and a fluid self-assembly method.

### BACKGROUND ART

With the development and progress of science and technology, the volumes of various electronic products are becoming increasingly compact, and devices are continuously developing towards miniaturization and integration. In this process, integrating microelectronic devices and micro-small components into corresponding drive circuits at high density to form applicable and producible electronic hardware has become an important technical route. How to assemble a large number of micro-devices efficiently, precisely, and at low cost has become a major challenge in this technical approach. Mass transfer technology has thus emerged as a result.

Mass transfer technology refers to a technology that arranges millions or even tens of millions of small-sized micro devices on a drive panel in an orderly manner. This technology effectively solves the problem of assembling and integrating a large number of micro devices in current microelectronic technology. In addition, the mass transfer technology of micro devices also has important application value in fields such as micro-chips, biology, and materials.

Fluid self-assembly, as one of the most promising mass transfer technologies, has received widespread attentions. Fluid self-assembly technology is to disperse micro devices into a fluid, use fluid force to drive their random movement in the fluid, make the micro devices fall into pre-fabricated special structures on the substrate, realizing filling and arrangement, and achieving the effect of self-assembly. The fluid self-assembly technology has the advantages of low cost, high efficiency, and wide application range, and has broad development prospects in fields such as micro-LED displays, flexible solar cells, and wearable devices.

However, in the existing fluid self-assembly technologies, the following technical problems still exist:
1. Insufficient assembly force between the micro devices and the assembly substrate. In the existing fluid self-assembly technology, there are mainly two assembly methods between the micro devices and the assembly substrate: shape matching and capillary force. In the assembly method of shape matching, after the micro device falls into the groove of the assembly substrate, the micro device may still disengage due to the influence of fluid flow; capillary force depends on the two-phase interface to exist, and the force disappears when leaving the liquid environment, causing difficulties for subsequent steps. Therefore, the fluid self-assembly based on the above two assembly forces may still separate after assembly, resulting in low assembly efficiency.
2. The assembly substrate needs to construct complex three-dimensional structures. In existing fluid self-assembly, to effectively capture micro devices moving randomly in the fluid, three-dimensional structures such as grooves or protrusions are usually provided on the assembly substrate. This realizes oriented assembly and arrangement of the micro devices on the assembly substrate through shape matching. However, the preparation of such three-dimensional structures involves a plurality of micro-nano manufacturing processes such as lithography and microfabrication, resulting in a complex preparation process.
3. The micro devices require special processing to achieve surface selectivity. In the fluid self-assembly process, the micro devices need to be assembled on the assembly substrate with a specific surface to realize a bonding process between the micro devices and the assembly substrate. For example, in the fluid self-assembly of micro-LEDs, it is necessary to bond the micro-LED chip electrode with the substrate electrode to realize circuit conduction and light-emitting display functions. However, the design of existing micro devices lacks a mechanism to adjust the assembly state of micro-nano devices, and requires additional structures to realize the regulation of the assembly front and back, increasing the complexity of preparation.
4. Difficult post-repair after micro device assembly. After the micro devices are assembled on the assembly substrate, it is also necessary to detect and repair the micro devices and replace failed micro devices. Existing fluid self-assembly technologies mostly use methods such as solder for fixation, which cannot achieve selective fixation and are difficult to remove after assembly, resulting in difficult post-repair.
5. A plurality of types of micro devices need to be processed step-by-step and batch-by-batch, with many and complex processes. For assembling multiple types of micro devices, there are currently two main solutions: classified assembly and multi-step assembly. Classified assembly relies on different shapes or surface modifications to realize simultaneous assembly of multiple types of micro devices. Therefore, classified assembly can be further divided into shape classified assembly and surface modification classified assembly. The shape classified assembly scheme requires preparing different micro structures into different shapes, and at the same time preparing shape-complementary groove structures at target positions on the assembly substrate, which additionally increases the complexity of micro device and substrate preparations. Surface modification classified assembly has low assembly efficiency and is difficult to realize assembly due to the high roughness and modulus of the substrate. Multi-step assembly refers to a method of sequentially assembling different types of micro devices with the same shape onto the same assembly substrate through a plurality of steps, that is, after the assembly of the first type of micro device is completed, the assembly of the second type of micro device is performed. This will additionally increase the preparation processes, causing the overall required process steps of the product to increase exponentially.

In view of this, existing fluid self-assembly technologies still have a series of problems such as low transfer efficiency, complex structures of micro devices and an assembly substrate, and difficulty in realizing simultaneous classified assembly of multiple types of micro devices on the same assembly substrate. There is an urgent need for a person skilled in the art to provide a new strategy to solve the above problems.

### SUMMARY OF THE INVENTION

### Objective of the Present Application

To this end, the embodiments of the present application provide a low-modulus supramolecular coating applied to micro devices and an assembly substrate and a fluid self-assembly technology to solve the problems existing in the prior art in whole or in part.

### Solution

In order to achieve the above objective, the embodiments of the present application provide the following technical solutions:
a low-modulus supramolecular coating, applied to micro devices and an assembly substrate, where a modulus of the low-modulus supramolecular coating is 10 MPa or less, and a surface has fluidity; and the low-modulus supramolecular coating is applied to the surfaces of micro devices and the surface of an assembly substrate, and the low-modulus supramolecular coating applied to the surfaces of the micro devices and the low-modulus supramolecular coating applied to assembly positions on the assembly substrate contain complementary supramolecular functional groups.

In some embodiments, the low-modulus supramolecular coating is composed of a variety of single or composite materials among hydrogel, layer-by-layer assembled multilayer film, and polymer brush.

In some embodiments, the low-modulus supramolecular coating is applied by one method selected from the group consisting of spin coating, dip coating, blade coating, digital lithography, layer-by-layer assembly technology, in-situ hydrogel polymerization and in-situ polymerized brush.

In some embodiments, the supramolecular functional groups include one of specific hybridization between two complementary DNA strands, reversible covalent bond represented by disulfide bond, specific biological recognition represented by biotin-avidin, host-guest interaction represented by cyclodextrin and azobenzene, electrostatic interaction between positive charges and negative charges, click chemical reaction represented by azide and alkyne, photochemical reaction represented by coumarin dimerization, coordination bond between ligands and receptors, hydrogen bond interaction, and charge transfer interaction.

In some embodiments, the low-modulus supramolecular coating is applied on surfaces of a plurality of single or composite materials among gallium nitride, silicon dioxide, silicon, metal, and polymer. In some embodiments, the low-modulus supramolecular coating is applied on surfaces of micro devices with cubic, rectangular, or cylindrical shapes.

In some embodiments, the low-modulus supramolecular coating can be selectively applied on a certain surface instead of other surfaces of the micro device, and the applied area is less than or equal to an area of the applied surface; the low-modulus supramolecular coating performs patterned specific modification on the surface of the assembly substrate at assembly positions instead of other positions, and partially or completely covers assembly positions of the assembly substrate.

The present application also provides a fluid self-assembly method for micro devices, which is implemented based on an assembly substrate and the micro devices applied with the low-modulus supramolecular coating as described above, where the method includes the following steps:
S1. Applying surfaces of various different types of a first micro device, a second micro device, and a third micro device to be transferred with low-modulus supramolecular coatings respectively, where the low-modulus supramolecular coatings respectively contain a supramolecular functional group A, a supramolecular functional group B, and a supramolecular functional group C;
S2. Performing patterned surface application on the assembly substrate, so that target positions are applied with a first patterned low-modulus supramolecular coating, a second patterned low-modulus supramolecular coating and a third patterned low-modulus supramolecular coating corresponding to the first micro device, the second micro device and the third micro device; where the first patterned low-modulus supramolecular coating, the second patterned low-modulus supramolecular coating and the third patterned low-modulus supramolecular coating contain a supramolecular functional group a, a supramolecular functional group b and a supramolecular functional group c, respectively;
S3. Placing the plurality of micro devices and the assembly substrate applied in a container with assembly solution, forcing the micro devices to move under mechanical disturbance. This method employs orthogonal and complementary supramolecular interactions. It utilizes supramolecular functional groups contained within a low-modulus supramolecular coating, which is applied to both the micro-device surface and the corresponding assembly sites on the substrate. This enables the simultaneous, classified, and oriented assembly of different types of micro-devices at their designated target locations on the assembly substrate.
S4. Transferring the assembly substrate assembled with multiple different types of micro devices to a next process, giving a specific stimulus to achieve shrinkage or removal of the low-modulus supramolecular coatings, and then completing bonding, inspection, repair and packaging processes between the micro devices and the substrate.

In some embodiments, the fluid self-assembly method described in step S3 includes:
during the assembly process, the side of the assembly substrate applied with the low-modulus supramolecular coating contacts with the solution, while the other side is attached to the wall of the assembly container;
disturbing, by a flow disturbing component in the assembly container, the assembly solution, and making the micro devices applied with the low-modulus supramolecular coatings move randomly in the assembly solution;
on the basis of the supramolecular interactions between complementary supramolecular functional groups, assembling the micro devices on the assembly substrate until each assembly position on the assembly substrate is assembled with one micro device, and then taking the assembly substrate assembled with the micro devices out from the fluid.

In some embodiments, the fluid self-assembly method described in step S4 includes:
taking an assembly of the micro devices and the assembly substrate out from the self-assembly container, under stimulations of heating, reduced pressure, irradiation, addition of solvent, the low-modulus supramolecular coatings realize shrinkage or decomposition, and finally the assembly completes bonding between the micro devices and the assembly substrate by thermocompression bonding, eutectic bonding or soldering.

### Beneficial Effects

The low-modulus supramolecular coating applied to micro devices and an assembly substrate and the fluid self-assembly method provided in the present application have at least the following technical effects:
1. The existence of supramolecular force makes its stability higher than those of assembly methods without supramolecular force. The supramolecular force is usually larger than capillary force, which can greatly improve the assembly stability of the devices and the substrate, thereby improving assembly efficiency. In addition, supramolecular interactions do not depend on the two-phase interface for their existence; thus, after assembly, they can be separated from the liquid environment and exist stably. Compared with capillary force that exists depending on the two-phase interface, the above-mentioned assembly dominated by supramolecular force is more conducive to the progress of subsequent processes.
2. There is no need to prepare shape-complementary micro devices and assembly substrate, which can greatly simplify the preparation process. The fluid self-assembly technology based on the low-modulus supramolecular coating only needs to use mature coating preparation methods to chemically apply the surface of the micro device and the assembly position of the assembly substrate, so as to realize an oriented assembly of the micro device on the surface of the assembly substrate by using specific supramolecular recognition, simplifying the preparation process and reducing production cost at the same time.
3. Based on the basic principle that supramolecular interaction has specificity, a selection of assembly surface can be realized. The assembly process of the low-modulus supramolecular coating has good selectivity, that is, only surfaces applied with complementary supramolecular functional groups can bind. Therefore, the micro device applied with the low-modulus supramolecular coating in the present application does not need to prepare additional structures, and can distinguish the assembly surface and non-assembly surface of the micro device only through the difference in the surface low-modulus supramolecular coating, so as to achieve high-precision surface-selectivity assembly.
4. Based on the basic principle that supramolecular interaction has reversibility, the post-repair difficulty can be effectively reduced. Low-modulus supramolecular coating has good reversibility after assembly, that is, the micro device applied with a low-modulus supramolecular coating can achieve disassembly under specific external stimuli after assembly with the assembly substrate. After a failed micro device is found, only specific stimulation needs to be applied locally, and the failed micro device can be disassembled and separated, significantly reducing the difficulty of the post-repair process.
5. The selection of multiple supramolecular interactions with orthogonal specificity can realize simultaneous assembly of different micro devices. Orthogonal specificity means that supramolecular functional group A only interacts with supramolecular functional group a to generate force, and does not interact with or exhibit a repulsive effect on other supramolecular functional groups such as supramolecular functional groups A, B, b, C, c, etc. Therefore, for the case where different micro devices need to be integrated into the same assembly substrate, the use of a plurality of orthogonal supramolecular interactions can perform co-assembly of different micro devices in the same process without adding additional structures to the micro devices, ensuring that each micro device is assembled to the target position at the same time without interfering with each other, thereby greatly simplifying the process and improving assembly efficiency.

In conclusion, the solution provided in the present application can solve the problems of low assembly efficiency of micro devices in fluid self-assembly, complex structures of assembly substrates and micro devices, difficult post-repair, and difficulty in realizing simultaneous classified assembly of a plurality of types of micro devices on the same assembly substrate.

### BRIEF DESCRIPTION OF THE DRAWINGS

To more clearly describe the embodiments of the present application or the technical solutions in the prior art, the following provides a brief description of the accompanying drawings required for the description of the embodiments or the prior art. Obviously, the drawings in the following description are only exemplary, and for a person skilled in the art, other implementation drawings can also be derived according to the provided drawings without creative efforts.

The structures, proportions, sizes, and the like as illustrated in this specification are only used to match the contents disclosed in the specification, for the understanding and reading of a person skilled in the art. They are not used to define the implementable conditions of the present application, thus having no substantial technical significance. Any modifications to structures, changes in proportional relationships, or adjustments to sizes shall still fall within the scope covered by the technical contents disclosed in the present application, provided that they do not affect the effects that the present application can produce and the objectives that it can achieve.

FIG. 1 is a structural schematic diagram of a specific embodiment of a chip according to the present application;

FIG. 2 is a cross-sectional view taken along the A-A direction in FIG. 1;

FIG. 3 is a structural schematic diagram of a specific embodiment of a substrate according to the present application;

FIG. 4 is a cross-sectional view taken along the C-C direction in FIG. 3;

FIG. 5 is a schematic structural diagram of a fluid self-assembly process according to an example;

FIG. 6 is a diagram illustrating a correct contact mode between a chip and a substrate in a fluid self-assembly process shown in FIG. 3;

FIG. 7 is a diagram illustrating an incorrect contact mode between a chip and a substrate during a fluid self-assembly process as shown in FIG. 3;

FIG. 8 is an assembly structure diagram in a fluid self-assembly process as shown in FIG. 3;

FIG. 9 is a structural schematic diagram of another specific embodiment of a chip according to the present application;

FIG. 10 is a cross-sectional view taken along the B-B direction in FIG. 9;

FIG. 11 is a structural schematic diagram of another specific embodiment of a substrate according to the present application;

FIG. 12 is a cross-sectional view taken along the D-D direction in FIG. 11;

FIG. 13 is an assembly structure diagram in a fluid self-assembly process in another embodiment;

FIG. 14 is a structural schematic diagram of another specific embodiment of a chip according to the present application;

FIG. 15 is a cross-sectional view taken along the A-A direction in FIG. 14;

FIG. 16 is a schematic structural diagram of yet another specific embodiment of a chip according to the present application;

FIG. 17 is a cross-sectional view taken along the B-B direction in FIG. 16;

FIG. 18 is a structural schematic diagram of another specific embodiment of a chip according to the present application;

FIG. 19 is a cross-sectional view taken along the B-B direction in FIG. 18.

### DESCRIPTION OF REFERENCE NUMERALS

100—micro-LED chip;
101—chip body, 102—first electrode, 103—second electrode;
104—low-modulus supramolecular coating A, 105—insulating layer, 106—low-modulus coating;
200—substrate;
201—substrate body, 202—third electrode, 203—fourth electrode, 204—low-modulus supramolecular coating a;
301—assembly container, 302—image monitoring system, 303—plunger pump;
401—thermocompression bonding plate.

### DETAILED DESCRIPTION OF THE INVENTION

The following describes the implementation of the present application through specific examples. A person skilled in the art can easily understand other advantages and effects of the present application from the contents disclosed in this specification. Obviously, the described examples are part of the examples of the present application, not all of the examples. Based on the examples in the present application, all other examples obtained by a person skilled in the art without creative efforts shall fall within the protection scope of the present application.

In a specific embodiment, the low-modulus supramolecular coating provided in the present application, which is applied to micro devices and an assembly substrate, has a modulus of 10 MPa or less and a surface thereof has fluidity; and the low-modulus supramolecular coating is applied to the surfaces of micro devices and the surface of an assembly substrate, and the low-modulus supramolecular coating applied to the surfaces of the micro devices and the low-modulus supramolecular coating applied to assembly positions on the assembly substrate contain complementary supramolecular functional groups. The low-modulus supramolecular coating may be composed of various single or composite materials such as hydrogel, layer-by-layer assembled multilayer film, polymer brush, etc., and the low-modulus supramolecular coating can be applied by various methods such as spin coating, dip coating, blade coating, digital lithography, layer-by-layer assembly technology, in-situ hydrogel polymerization, in-situ polymerized brush, etc. The preparation process of the low-modulus supramolecular coating can be directly introducing supramolecular functional groups during the polymerization process of the low-modulus supramolecular coating to synthesize the low-modulus supramolecular coating containing supramolecular functional groups via a one-step method; or first applying the low-modulus coating and then introducing the supramolecular functional groups through surface modification via a two-step synthesis.

In some embodiments, the supramolecular functional groups include all chemical functional group combinations that can interact within a short period of time, for example, specific hybridization between two complementary DNA strands, reversible covalent bond represented by disulfide bond, specific biological recognition represented by biotin-avidin, host-guest interaction represented by cyclodextrin and azobenzene, electrostatic interaction between positive charges and negative charges, click chemical reaction represented by azide and alkyne, photochemical reaction represented by coumarin dimerization, coordination bond between ligands and receptors, hydrogen bond interaction, and charge transfer interaction, etc.

The low-modulus supramolecular coating can be applied on surfaces of various single or composite materials among gallium nitride, silicon dioxide, silicon, metal, polymer, etc. Specifically, the low-modulus supramolecular coating can be applied on surface of micro devices with any columnar structure such as cube, cuboid, cylinder, etc.; it can also be applied on the surface of assembly substrates with any shape such as plane, cylinder, curved surface, etc. In addition, the low-modulus supramolecular coating has no restriction on the shape of the applied surface, which can be any surface morphology such as patterned protrusion/patterned groove/flat surface.

Preferably, the low-modulus supramolecular coating can achieve selective application. The low-modulus supramolecular coating can be selectively applied on any surface of the micro device, other surfaces are not applied, and the applied area is less than or equal to the area of the applied surface. The low-modulus supramolecular coating can perform patterned specific modification on the surface of the assembly substrate. The low-modulus supramolecular coating is applied at assembly positions instead of other positions, and partially or completely covers the assembly positions of the assembly substrate.

Based on the above assembly substrate and the micro devices applied with low-modulus supramolecular coatings, the present application also provides a fluid self-assembly method for micro devices, where the method includes the following steps:
S1. Applying surfaces of various different types of a first micro device, a second micro device, and a third micro device to be transferred with low-modulus supramolecular coatings respectively, where the low-modulus supramolecular coatings respectively contain a supramolecular functional group A, a supramolecular functional group B, and a supramolecular functional group C;
S2. Performing patterned surface application on the assembly substrate, so that target positions are applied with a first patterned low-modulus supramolecular coating, a second patterned low-modulus supramolecular coating and a third patterned low-modulus supramolecular coating corresponding to the first micro device, the second micro device and the third micro device; where the first patterned low-modulus supramolecular coating, the second patterned low-modulus supramolecular coating and the third patterned low-modulus supramolecular coating contain a supramolecular functional group a, a supramolecular functional group b and a supramolecular functional group c, respectively;
S3. Placing the plurality of micro devices and the assembly substrate applied in a container with assembly solution, forcing the micro devices to move under mechanical disturbance. This method employs orthogonal and complementary supramolecular interactions. It utilizes supramolecular functional groups contained within a low-modulus supramolecular coating, which is applied to both the micro-device surface and the corresponding assembly sites on the substrate. This enables the simultaneous, classified, and oriented assembly of different types of micro-devices at their designated target locations on the assembly substrate.
S4. Transferring the assembly substrate assembled with multiple different types of micro devices to a next process, giving a specific stimulus to achieve shrinkage or removal of the low-modulus supramolecular coatings, and then completing bonding, inspection, repair and packaging processes between the micro devices and the substrate.

Wherein, the fluid self-assembly method described in step S3 includes:
during the assembly process, the side of the assembly substrate applied with the low-modulus supramolecular coating contacts with the solution, while the other side is attached to the wall of the assembly container;
disturbing, by a flow disturbing component in the assembly container, the assembly solution, and making the micro devices applied with the low-modulus supramolecular coatings move randomly in the assembly solution. The flow disturbance method can be various methods such as plunger pump, circulation pump, peristaltic pump, brush, shaking table, oscillation, centrifugation and other methods.

On the basis of the supramolecular interactions between complementary supramolecular functional groups, assembling the micro devices on the assembly substrate until each assembly position on the assembly substrate is assembled with one micro device, and then taking the assembly substrate assembled with the micro devices out from the fluid.

Wherein, the fluid self-assembly method described in step S4 includes:
taking an assembly of the micro devices and the assembly substrate out from the self-assembly container, under stimulations of heating, reduced pressure, irradiation, addition of solvent, the low-modulus supramolecular coatings realize shrinkage or decomposition, and finally the assembly completes bonding between the micro devices and the assembly substrate by thermocompression bonding, eutectic bonding or soldering, realizing electrical conductivity, thermal conductivity, and other functions. The bonded assembly continues to complete the subsequent inspection and packaging process.

The number of types of the above-mentioned micro device is n, where n is a natural number and n≥1. The supramolecular interactions are n pairs and have specificity, that is, the used supramolecular functional group A only reacts with the supramolecular functional group a, and does not react with supramolecular functional groups A, B, b, C, c and other supramolecular functional groups or have a repulsive effect.

For ease of understanding, below are several specific examples taken as examples to briefly describe the implementation process of the solution provided by the present application.

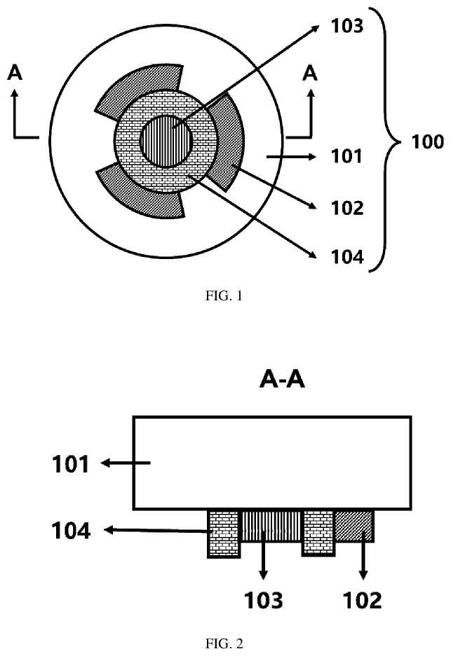

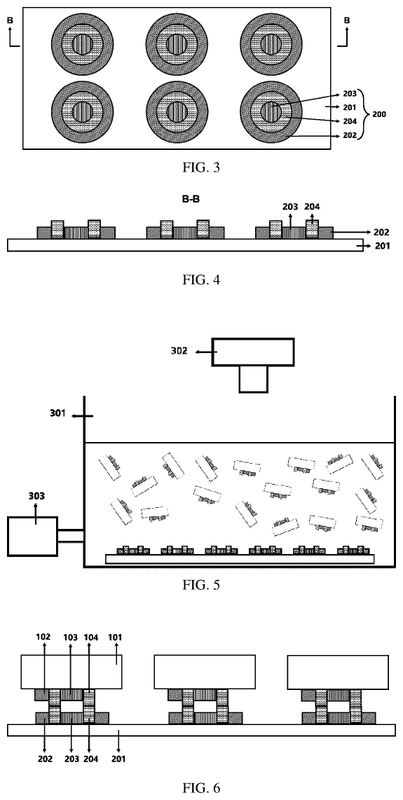

Example 1, a fluid self-assembly process of monochromatic micro-LED chip includes the following steps:
S101. Preparation of a micro-LED chip 100. As shown in FIGS. 1 and 2, first, a micro-LED chip structure was fabricated on a substrate, and its shape can be circular, square, hexagonal, and other various shapes; herein, a circular micro-LED chip 100 was taken as an example. A circuit structure including a first electrode 102 and a second electrode 103 was constructed on the surface of the prepared chip 100. The first electrode 102 was a multi-segment discontinuous annular structure, the second electrode 103 was circular, and both were nested rotationally symmetric structures. A low-modulus supramolecular coating A 104 containing a supramolecular functional group A was filled between the two electrodes, on the one hand, acting as an insulating layer to isolate the first electrode 102 from the second electrode 103, and on the other hand, utilizing the contained supramolecular functional groups to realize the assembly process. The supramolecular functional group A can be a positively charged polyelectrolyte (such as polyethyleneimine, polydiallyldimethylammonium chloride, etc.). The low-modulus supramolecular coating can be composed of various single or composite materials such as hydrogel, layer-by-layer assembled multilayer film, polymer brush, etc., and the low-modulus supramolecular coating can be applied by various methods such as spin coating, dip coating, blade coating, digital lithography, layer-by-layer assembly technology, in-situ hydrogel polymerization, in-situ polymerized brush, etc.
S102. Design and fabrication of an assembly substrate 200. As shown in FIGS. 3 and 4, an assembly substrate 200 was composed of a substrate body 201, a third electrode 202, a fourth electrode 203, and a low-modulus supramolecular coating a 204. A circuit structure including the third electrode 202 and the fourth electrode 203 were prepared on the surface of the substrate body 201, the shape of which was consistent with the electrode shape in the micro-LED chip 100. Here, a circle was still taken as an example. The third electrode 202 was a continuous circular ring structure located on the outer side, inside which was a circular fourth electrode 203 located on the inner side, which was consistent with the electrode structure on the micro-LED chip 100 and was a nested rotationally symmetric structure. Filled between the two electrodes was a low-modulus supramolecular coating a 204 containing a supramolecular functional group a, which on the one hand functioned as an insulating layer to isolate the third electrode 202 and the fourth electrode 203; on the other hand, utilized the supramolecular functional group it contained to achieve the assembly process. The supramolecular functional group a was a negatively charged polyelectrolyte (such as polyacrylic acid, hyaluronic acid, etc.). The low-modulus supramolecular coating can be composed of various single or composite materials such as hydrogel, layer-by-layer assembled multilayer film, polymer molecular brush, etc., and the low-modulus supramolecular coating can be applied by various methods such as spin coating, dip coating, blade coating, digital lithography, layer-by-layer assembly technology, in-situ hydrogel polymerization, in-situ polymerized brush, etc.
S103. Fluid self-assembly process. The fluid self-assembly process was shown in FIG. 5, and the assembly medium was low-viscosity liquids such as water. Under external disturbance, the assembly medium moved randomly in the assembly container 301 and drove the motion of the micro-LED chip 100 therein. External disturbance can be achieved by various methods such as brush drive, circulation pump, plunger pump, vertical oscillation, and centrifugation.

When the micro-LED chip 100 was assembled to the assembly substrate 200 in a manner shown in FIG. 6, the low-modulus supramolecular coating A 104 on the micro-LED chip 100 and the low-modulus supramolecular coating a 204 on the assembly substrate 200 can fix the micro-LED chip 100 on the assembly substrate 200 based on electrostatic interaction between positive charges and negative charges, preventing it from being washed away by fluid. The image monitoring system 302 above the device monitored and fed back the assembly process in real time, including information such as filling rate and precision. After the micro-LED chip 100 was assembled at each electrode position on the assembly substrate 200, the control system would stop turbulence, causing the assembly of the micro-LED chip 100 and the assembly substrate 200 to enter the next process.

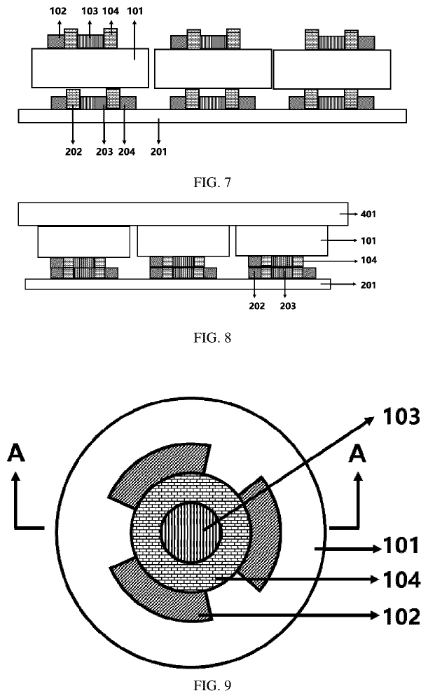

FIG. 7 shows an incorrect contact mode between the micro-LED chip 100 and the assembly substrate 200. In this contact mode, since there was no interaction between the low-modulus supramolecular coating a 204 and the chip body 101 of the micro-LED chip 100 without coating application, the structure cannot exist stably, and the micro-LED chip 100 was easily washed away by fluid. Subsequently, the micro-LED chip 100 continued to move in the assembly medium and interacted with the assembly substrate 200 until the designed correct assembly state was achieved.
S104. Bonding, inspection and packaging processes of the Micro-LED chip 100 and the assembly substrate 200. As shown in FIG. 8, after the correct assembly of the micro-LED chip 100 and the assembly substrate 200 was completed in the fluid, it proceeded to the next process to complete bonding, inspection, and packaging. The low-modulus supramolecular coating A 104 and the low-modulus supramolecular coating 204 shrunk and shortened under the stimulation of external conditions, enabling the first electrode 102 to achieve contact with the third electrode 202, and the second electrode 103 to achieve contact with the fourth electrode 203, thus forming a complete circuit structure. After the shrinkage, the low-modulus supramolecular coating still remained between the two electrodes, serving as an insulating layer. Here, the external stimuli can include methods such as adding a hot pressing plate 401 above the micro-LED chip 100, evacuating, introducing dry hot air, etc. The Micro-LED chip 100 and the assembly substrate 200 utilized eutectic bonding, solder connection, silver/copper sintering and other methods to complete the bonding process, and subsequently complete the inspection and packaging processes.

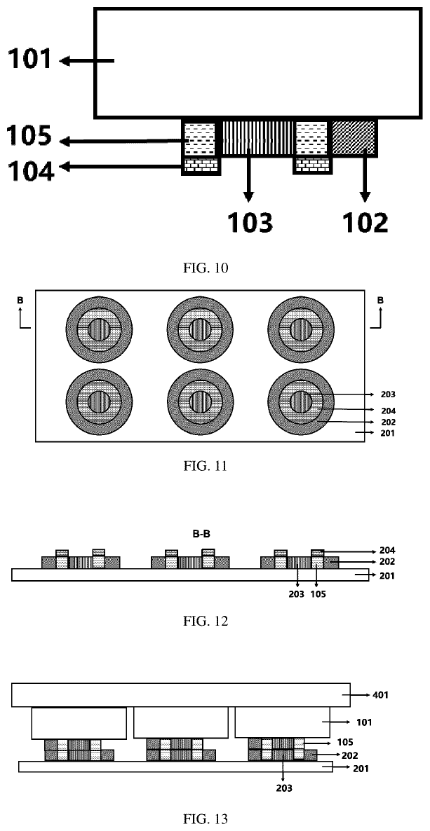

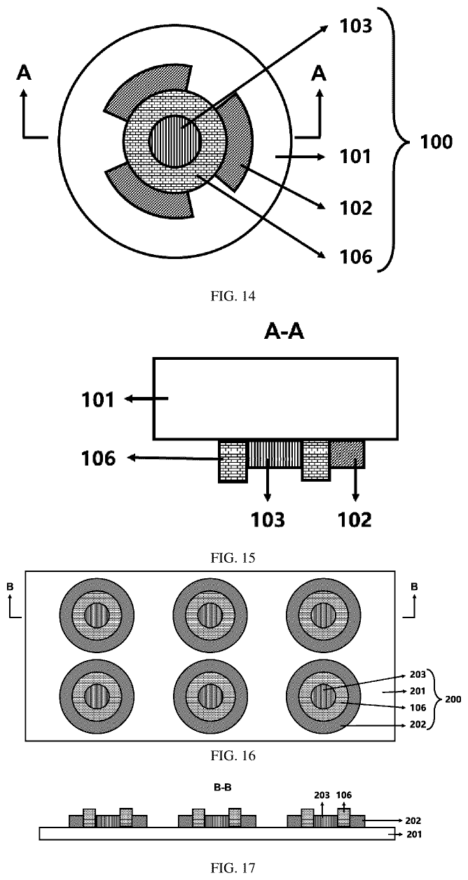

Example 2, a fluid self-assembly process of monochromatic micro-LED chip includes the following steps:
S201. Preparation of a micro-LED chip 100. The structure of the Micro-LED chip 100 was shown in FIGS. 9 and 10, and the circuit structure and fabrication process of the Micro-LED chip 100 were consistent with Example 1. An insulating layer 105 was prepared between the prepared first electrode 102 and second electrode 103, and the low-modulus supramolecular coating A 104 was applied on the insulating layer 105, the application process thereof being consistent with the application process in Example 1.
S202. Design and fabrication of an assembly substrate 200. The design of the circuit structure of the assembly substrate 200 was consistent with that in Example 1. The structure of the assembly substrate 200 was shown in FIGS. 11 and 12. The insulating layer 105 was prepared between the prepared third electrode 202 and fourth electrode 203, and a low-modulus supramolecular coating a 204 was applied on the insulating layer 105, the application process thereof being consistent with the application process in Example 1.
S203. The fluid self-assembly process was consistent with the assembly process in Example 1.
S204. Bonding, inspection and packaging processes of the micro-LED chip 100 and the assembly substrate 200. As shown in FIG. 13, after the correct assembly of the micro-LED chip 100 and the assembly substrate 200 was completed in the fluid, the steps of bonding, inspection and packaging were performed. A specific stimulus was applied to the assembly, the low-modulus supramolecular coating A 104 and the low-modulus supramolecular coating a 204 between the micro-LED chip 100 and the assembly substrate 200 turned into liquid or gas by means of decomposition liquefaction or decomposition sublimation, and flowed away from the gaps of the micro-LED chip 100 or volatilized. Meanwhile, the first electrode 102 of the micro-LED chip 100 and the third electrode 202 of the assembly substrate 200, the second electrode 103 of the micro-LED chip 100 and the fourth electrode 203 of the assembly substrate 200, and the insulating layer 105 of the micro-LED chip 100 and the insulating layer 105 of the assembly substrate 200 contacted each other, forming a complete circuit structure. The micro-LED chip 100 and the assembly substrate 200 utilized eutectic bonding, solder connection, silver/copper sintering and other methods to complete the bonding process, and subsequently complete the inspection and packaging processes.

Example 3, a fluid self-assembly process of monochromatic micro-LED chip 100 includes the following steps:
S301.Preparation of a Micro-LED chip 100. The preparation processes of the Micro-LED chip 100 and the circuit was the same as those of Example 1, as shown in FIGS. 14 and 15. A low-modulus coating 106 was filled between the two electrodes, which only reduced the surface modulus, did not contain any supramolecular functional group, and at the same time served as an insulating layer to isolate the first electrode 102 from the second electrode 103. On the surface of the low-modulus coating 106, surface modified method was used to apply a supramolecular functional group A. The supramolecular functional group A was a positively charged supramolecular functional group (such as amino group, etc.). The low-modulus coating 106 and the surface-applied supramolecular functional group cooperatively formed a low-modulus supramolecular coating. The low-modulus coating 106 was composed of various single or composite materials such as hydrogel, layer-by-layer assembled multilayer film, polymer brush, etc. ; it can be applied by various methods such as spin coating, dip coating, blade coating, digital lithography, layer-by-layer assembly technology, in-situ hydrogel polymerization, in-situ polymerized brush, etc. Surface supramolecular functional groups can be applied by methods such as surface polymerization, layer-by-layer assembly technology, surface-initiated radical polymerization, soaking, etc.
S302. Design of an assembly substrate 200. The preparation process and circuit structure of the assembly substrate 200 were consistent with those of Example 1. As shown in FIGS. 16 and 17, a low-modulus coating 106 was filled between the two electrodes. The low-modulus coating 106 functioned as an insulating layer, isolating the third electrode 202 and the fourth electrode 203. On the surface of the applied low-modulus coating 106, a surface modified method was used to apply the supramolecular functional group a. The supramolecular functional group a can be a negatively charged supramolecular functional group (such as carboxyl group, carboxylate, sulfonic acid group, phosphoric acid group, etc.). The low-modulus coating 106 and the surface-applied supramolecular functional group cooperatively formed a low-modulus supramolecular coating. The low-modulus coating was composed of various single or composite materials such as hydrogel, layer-by-layer assembled multilayer film, and polymer brush; applied by various methods such as spin coating, dip coating, blade coating, digital lithography, layer-by-layer assembly technology, in-situ hydrogel polymerization, and in-situ polymerized molecular brush; surface supramolecular functional groups can be applied by methods such as surface polymerization, layer-by-layer assembly technology, surface-initiated radical polymerization, and soaking.
S303. The fluid self-assembly process was consistent with that of Example 1.
S304. Bonding, inspection and packaging processes of the Micro-LED chip 100 and the assembly substrate 200 were consistent with those in Example 1.

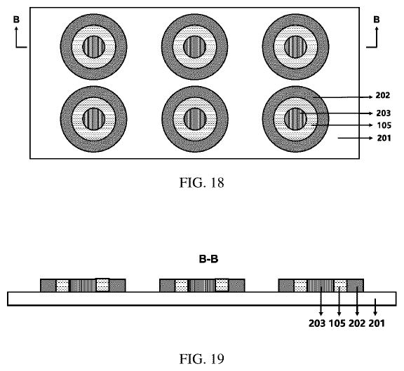

Example 4, a fluid self-assembly process of monochromatic micro-LED chip 100 includes the following steps:
S401. Preparation of a Micro-LED chip 100, the preparation process of micro-LED chip 100 was consistent with that of Example 2.
S402. Design of an assembly substrate 200. The design of the circuit and insulating structure of the assembly substrate 200 was consistent with that in Example 2. The assembly substrate 200 had a structure as shown in FIGS. 18 and 19, with a supramolecular functional group a applied on the surface of the prepared insulating layer 105 located between the third electrode 202 and the fourth electrode 203. No additional low-modulus coating application was needed here, and direct surface application of functional group a was sufficient. The supramolecular functional group a can be a negatively charged supramolecular functional group (such as carboxyl group, carboxylate, sulfonic acid group, phosphoric acid group, etc.). Surface supramolecular functional groups can be applied by surface polymerization, layer-by-layer assembly technology, surface-initiated radical polymerization, surface vapor deposition and other methods.
S403. The fluid self-assembly process was consistent with the assembly process in Example 1.
S404. Bonding, inspection and packaging processes were consistent with the processes in Example 2.

Example 5, a three-color full-colorization fluid self-assembly of Micro-LED includes the following steps:
S501. Preparation process of a micro-LED chip 100. The circuit structure and preparation process of each micro-LED chip were consistent with the preparation process of step S101 in Example 1. The supramolecular functional groups contained in the low-modulus supramolecular coatings on the three-color micro-LED chips 100 were different. The red micro-LED chip 100 contained a supramolecular functional group A; the green micro-LED chip 100 contained a supramolecular functional group B; the blue micro-LED chip 100 contained a supramolecular functional group C.
S502. Preparation process of an assembly substrate 200. The structure and preparation process of the assembly substrate 200 were consistent with step S102 in Example 1. The low-modulus supramolecular coatings on the predetermined assembly positions of the three-color micro-LED chips contained different supramolecular functional groups. The supramolecular functional group contained in the assembly position of the red micro-LED chip 100 was a; the supramolecular functional group contained in the assembly position of the green micro-LED chip 100 was b; the supramolecular functional group contained in the assembly position of the blue micro-LED chip 100 was c. Here, the supramolecular functional group applied on the micro-LED chip 100 and the supramolecular recognition functional group applied on the assembly substrate 200 can achieve specific orthogonal interaction based on the basic principles of supramolecular chemistry, that is, the supramolecular functional group A only had an interaction with the supramolecular functional group a, and had no interaction with b and c. The three were independent of each other and did not affect each other. Here, the supramolecular functional groups included all chemical functional group combinations that can interact within a short period of time, for example, specific hybridization between two complementary DNA strands, reversible covalent bond represented by disulfide bond, specific biological recognition represented by biotin-avidin, host-guest interaction represented by cyclodextrin and azobenzene, electrostatic interaction between positive charges and negative charges, click chemical reaction represented by azide and alkyne, photochemical reaction represented by coumarin dimerization, coordination bond between ligands and receptors, hydrogen bond interaction, and charge transfer interaction, etc.
S503. Fluid self-assembly process. The operation steps were consistent with the operation steps of S103 in Example 1. Three types of micro-LED chips 100 applied with different supramolecular functional groups were simultaneously placed in a fluid; based on the basic principles of supramolecular chemistry, the low-modulus supramolecular coating containing a functional group A can only assemble with the low-modulus supramolecular coating containing a functional group a, cannot assemble with low-modulus supramolecular coatings containing other functional groups, and also cannot assemble with sites not applied with low-modulus supramolecular coatings. By analogy, low-modulus supramolecular coatings containing a functional groups B can only assemble with low-modulus supramolecular coatings containing a functional group b, and low-modulus supramolecular coatings containing a functional group C can only assemble with low-modulus supramolecular coatings containing a functional group c. The problem of selective assembly between the three-color micro-LED chip 100 and the substrate was solved, and the micro-LED chips 100 with red, green, and blue emission colors can be synchronously filled, which can improve the efficiency of the full-color micro-LED display technology.
S504. Bonding, inspection and packaging processes of the Micro-LED chip 100 and the substrate 200. This step was consistent with step S104 in Example 1.

Example 6, the three-color full-colorization fluid self-assembly of Micro-LED includes the following steps:
S601. Preparation process of a micro-LED chip 100. The preparation process of each micro-LED chip 100 and the circuit was consistent with the preparation process of step S201 in Example 2. The supramolecular functional groups contained in the low-modulus supramolecular coatings on the three-color micro-LED chips 100 were different. The red micro-LED chip 100 contained a supramolecular functional group A; the green micro-LED chip 100 contained a supramolecular functional group B; the blue micro-LED chip 100 contained a supramolecular functional group C.
S602. Preparation process of an assembly substrate 200. The structure and preparation process of the assembly substrate 200 were consistent with step S202 in Example 2. The low-modulus supramolecular coatings on the predetermined assembly positions of the three-color micro-LED chips contained different supramolecular functional groups. The supramolecular functional group contained in the assembly position of the red micro-LED chip 100 was a; the supramolecular functional group contained in the assembly position of the green micro-LED chip 100 was b; the supramolecular functional group contained in the assembly position of the blue micro-LED chip 100 was c. Here, the supramolecular functional group applied on the micro-LED chip 100 and the supramolecular recognition functional group applied on the assembly substrate 200 can achieve specific orthogonal interaction based on the basic principles of supramolecular chemistry, that is, the supramolecular functional group A only had an interaction with the supramolecular functional group a, and had no interaction with b and c. The three were independent of each other and did not affect each other. Here, the supramolecular functional groups included all chemical functional group combinations that can interact within a short period of time, for example, specific hybridization between two complementary DNA strands, reversible covalent bond represented by disulfide bond, specific biological recognition represented by biotin-avidin, host-guest interaction represented by cyclodextrin and azobenzene, electrostatic interaction between positive charges and negative charges, click chemical reaction represented by azide and alkyne, photochemical reaction represented by coumarin dimerization, coordination bond between ligands and receptors, hydrogen bond interaction, and charge transfer interaction, etc.
S603. Fluid self-assembly process. The operation steps were completely consistent with the processes in S503 of Example 5.
S604. Bonding, inspection and packaging processes of the Micro-LED chip 100 and the substrate 200. This step was consistent with step S604 in Example 6.

The low-modulus supramolecular coating applied to micro devices and an assembly substrate and the fluid self-assembly method provided in the present application have at least the following technical effects:
1. The existence of supramolecular force makes its stability higher than those of assembly methods without supramolecular force. The supramolecular force is usually larger than capillary force, which can greatly improve the assembly stability of the devices and the substrate, thereby improving assembly efficiency. In addition, supramolecular interactions do not depend on the two-phase interface for their existence; thus, after assembly, they can be separated from the liquid environment and exist stably. Compared with capillary force that exists depending on the two-phase interface, the above-mentioned assembly dominated by supramolecular force is more conducive to the progress of subsequent processes.
2. There is no need to prepare micro devices with special three-dimensional structures and assembly substrates, which can greatly simplify the preparation process. The fluid self-assembly technology based on the low-modulus supramolecular coating only needs to use mature coating preparation methods to chemically apply the surface of the micro device and the surface of the assembly substrate, so as to realize an oriented assembly of the micro device on the surface of the assembly substrate by using specific supramolecular recognition, simplifying the preparation process and reducing production cost at the same time.
3. Based on the basic principle that supramolecular interaction has specificity, a selection of assembly surface can be realized. The assembly process of the low-modulus supramolecular coating has good selectivity, that is, only surfaces applied with complementary supramolecular functional groups can bind. Therefore, the micro device applied with the low-modulus supramolecular coating in the present application does not need to prepare additional structures, and can distinguish the front and back sides of the micro device only through the difference in surface chemistry, so as to achieve high-precision surface-selectivity assembly.
4. Based on the basic principle that supramolecular interaction has reversibility, the post-repair difficulty can be effectively reduced. Low-modulus supramolecular coating has good reversibility after assembly, that is, the micro device applied with a low-modulus supramolecular coating can achieve disassembly under specific external stimuli after assembly with the assembly substrate. After a failed micro device is found, only specific stimulation needs to be applied locally, and the failed micro device can be disassembled and separated, significantly reducing the difficulty of the post-repair process.
5. The selection of multiple supramolecular interactions with orthogonal specificity can realize simultaneous assembly of different micro devices. Orthogonal specificity means that supramolecular functional group A only interacts with supramolecular functional group a to generate force, and does not interact with or exhibit a repulsive effect on other supramolecular functional groups such as supramolecular functional groups A, B, b, C, c, etc. Therefore, for the case where different micro devices need to be integrated into the same assembly substrate, the use of a plurality of orthogonal supramolecular interactions can perform co-assembly of different micro devices in the same process without adding additional structures to the micro devices, ensuring that each micro device is assembled to the target position at the same time without interfering with each other, thereby greatly simplifying the process and improving assembly efficiency.

In conclusion, the solution provided in the present application can solve the problems in the prior art of low assembly efficiency of micro devices in fluid self-assembly, complex structures of assembly substrates and micro devices, difficult post-repair, and difficulty in realizing simultaneous classified assembly of a plurality of types of micro devices on the same assembly substrate.

The above specific embodiments further describe in detail the purpose, technical solution and beneficial effects of the present application. It should be understood that the above are only specific embodiments of the present application and are not intended to limit the protection scope of the present application. Any applications, equivalent substitutions, improvements, etc., made on the basis of the technical solution of the present application shall be included within the protection scope of the present application.

1. A low-modulus supramolecular coating, applied to micro devices and an assembly substrate, wherein a modulus of the low-modulus supramolecular coating is 10 MPa or less, and a surface thereof has fluidity; and the low-modulus supramolecular coating is applied to the surfaces of micro devices and the surface of an assembly substrate, and the low-modulus supramolecular coating applied to the surfaces of the micro devices and the low-modulus supramolecular coating applied to assembly positions on the assembly substrate contains complementary supramolecular functional groups.

2. The low-modulus supramolecular coating according to claim 1, wherein the low-modulus supramolecular coating is composed of a variety of single or composite materials among hydrogel, layer-by-layer assembled multilayer film, and polymer brush.

3. The low-modulus supramolecular coating according to claim 1, wherein the low-modulus supramolecular coating is applied by one method selected from the group consisting of spin coating, dip coating, blade coating, digital lithography, layer-by-layer assembly technology, in-situ hydrogel polymerization and in-situ polymerized brush.

4. The low-modulus supramolecular coating according to claim 1, wherein the supramolecular functional groups are one of specific hybridization between two complementary DNA strands, reversible covalent bond represented by disulfide bond, specific biological recognition represented by biotin-avidin, host-guest interaction represented by cyclodextrin and azobenzene, electrostatic interaction between positive charges and negative charges, click chemical reaction represented by azide and alkyne, photochemical reaction represented by coumarin dimerization, coordination bond between ligands and receptors, hydrogen bond interaction, and charge transfer interaction.

5. The low-modulus supramolecular coating according to claim 1, wherein the low-modulus supramolecular coating is applied on surfaces of a plurality of single or composite materials among gallium nitride, silicon dioxide, silicon, metal, and polymer.

6. The low-modulus supramolecular coating according to claim 1, wherein the low-modulus supramolecular coating is applied on surfaces of micro devices with cubic, rectangular, or cylindrical shapes.

7. The low-modulus supramolecular coating according to claim 1, wherein the low-modulus supramolecular coating is selectively applied on a certain surface instead of other surfaces of the micro device, and the applied area is less than or equal to an area of the applied surface; the low-modulus supramolecular coating performs patterned specific modification on the surface of the assembly substrate at assembly positions instead of other positions, and partially or completely covers assembly positions of the assembly substrate.

8. A fluid self-assembly method for micro devices, implemented based on an assembly substrate and micro devices applied with the low-modulus supramolecular coating according to claim 1, wherein the method comprises the following steps:
S1. Applying surfaces of various different types of a first micro device, a second micro device, and a third micro device to be transferred with low-modulus supramolecular coatings respectively, where the low-modulus supramolecular coatings respectively contain a supramolecular functional group A, a supramolecular functional group B, and a supramolecular functional group C;
S2. Performing patterned surface application on the assembly substrate, so that target positions are applied with a first patterned low-modulus supramolecular coating, a second patterned low-modulus supramolecular coating and a third patterned low-modulus supramolecular coating corresponding to the first micro device, the second micro device and the third micro device; where the first patterned low-modulus supramolecular coating, the second patterned low-modulus supramolecular coating and the third patterned low-modulus supramolecular coating contain a supramolecular functional group a, a supramolecular functional group b and a supramolecular functional group c, respectively;
S3. Placing the plurality of micro devices and the assembly substrate applied in a container with assembly solution, forcing the micro devices to move under mechanical disturbance; this method employs orthogonal and complementary supramolecular interactions and utilizes supramolecular functional groups contained within a low-modulus supramolecular coating, which is applied to both the micro-device surface and the corresponding assembly sites on the substrate; this enables the simultaneous, classified, and oriented assembly of different types of micro-devices at their designated target locations on the assembly substrate;
S4. Transferring the assembly substrate assembled with a plurality of different types of micro devices to a next process, giving a specific stimulus to achieve shrinkage or removal of the low-modulus supramolecular coatings, and then completing bonding, inspection, repair and packaging processes between the micro devices and the substrate.

9. The fluid self-assembly method according to claim 8, wherein the self-assembly method in step S3 comprises:
during the assembly process, the side of the assembly substrate applied with the low-modulus supramolecular coating contacts with the solution, while the other side is attached to the wall of the assembly container;
disturbing, by a flow disturbing component in the assembly container, the assembly solution, and making the micro devices applied with the low-modulus supramolecular coatings move randomly in the assembly solution;
on the basis of the supramolecular interactions between complementary supramolecular functional groups, assembling the micro devices on the assembly substrate until each assembly position on the assembly substrate is assembled with one micro device, and then taking the assembly substrate assembled with the micro devices out from the fluid.

10. The fluid self-assembly method according to claim 8, wherein the fluid self-assembly method in step S4 comprises:
taking an assembly of the micro devices and the assembly substrate out from the self-assembly container, under stimulations of heating, reduced pressure, irradiation, addition of solvent, the low-modulus supramolecular coatings realize shrinkage or decomposition, and finally the assembly completes bonding between the micro devices and the assembly substrate by thermocompression bonding, eutectic bonding or soldering.
